(19) United States
(12) Patent Application Publication
(10) Pub. No.: US 2021/0082792 A1
(43) Pub. Date: Mar. 18, 2021

(54) ELECTRICAL DEVICE WITH TERMINAL NOTCHES AND METHOD FOR MANUFACTURING THE SAME

(71) Applicant: TAIWAN SEMICONDUCTOR CO., LTD., New Taipei City (TW)

(72) Inventors: Chien-Chung CHEN, New Taipei City (TW); Sen MAO, New Taipei City (TW); Peng YEH, New Taipei City (TW)

(21) Appl. No.: 16/661,384

(22) Filed: Oct. 23, 2019

(30) Foreign Application Priority Data
Sep. 12, 2019 (TW) 108133068

(51) Int. Cl. H01L 23/495; H01L 21/48; H01L 23/00

(52) U.S. Cl. CPC H01L 23/49565; H01L 23/49582; H01L 2224/45144; H01L 24/48; H01L 2224/48175; H01L 21/4842

(57) ABSTRACT

An electric device with terminal notches includes a main body, a plurality of SMT leads and a plurality of plating layers. Each of the SMT leads is extended from the main body and ended up with a lead end surface furnished with a terminal notch, where the terminal notch has a notch peripheral surface. Each of the plating layers covers at least the notch peripheral surface of the corresponding SMT lead. In addition, a method for manufacturing the same electric device with terminal notches is also provided.

This application claims the benefit of Taiwan Patent Application Serial No. 108133068, filed on Sep. 12, 2019, the subject matter of which is incorporated herein by reference.

### BACKGROUND OF THE INVENTION

### (1) Field of the Invention

The invention relates to an electric device and a method for manufacturing the same electric device, and more particularly to an electric device with terminal notches and a method for manufacturing the same electric device.

### (2) Description of the Prior Art

Refer now to FIG. 1 through FIG. 5A; where FIG. 1 is a schematic view of an assembly of four conventional electric devices, FIG. 2 is a schematic view of the four conventional electric devices of FIG. 1 after being separated, FIG. 3 is a schematic perspective view of the conventional electric device of FIG. 2, FIG. 4 is a schematic cross-sectional view of FIG. 3 along line A-A, FIG. 4A is a schematic enlarged view of area B of FIG. 4, FIG. 5 is a schematic view of the conventional electric device of FIG. 4 on a circuit board, and FIG. 5A is a schematic enlarged view of area C of FIG. 5.

As shown in FIG. 1, in a typical conventional method for manufacturing electric devices, an assembly of plural electric devices (four shown in the figure) connected together is prepared, in which each of the electric device has a main body PA11 and a plurality of connection leads PA20. Then, a plating process is performed thereupon so as to coat a plating layer PA13 upon the assembly, including all the connection leads PA20. As shown in FIG. 2, after the plating process, the assembly is cut at the connection leads PA20, so as to form isolated electric devices PA1, in which each of the electric devices PA1 has its own leads PA12 cut from the corresponding connection leads PA20.

As shown in FIG. 3, the electric device PA1 includes a main body PA11, a plurality of leads PA12 and the corresponding plating layers PA13 on the corresponding leads PA12, in which each of the leads PA12 is extended from the main body PA11, and each of the plating layers PA13 covers a portion of the corresponding lead PA12.

Furthermore, each of the leads PA12 has a top surface PA121, a bottom surface PA122 and a lateral surface PA123. Since the lateral surface PA123 is formed after the corresponding connection lead PA20 is cut, thus the plating layers PA13 are only formed to coat the top surface PA121 and the bottom surface PA122 of the lead PA122, excluding the lateral surface PA123, as shown in FIG. 4 and FIG. 4A.

Generally speaking, a solder PAS is introduced to bind the lead PA12 of the electric device PA1 onto a circuit board PA2. However, since the lateral surface PA123 of the lead PA12 is not coated by the plating layer PA13, thus the solder PAS is not easy to be firmly added onto the lateral surface PA123. Thereupon, the effective contact area of the solder on the leads PA12 will be reduced, and from which the associated weld strength would be reduced as well. Namely, reduction in the weld reliability of the electric device PA1 on the circuit board would be a concern. As shown in FIG. 5 and FIG. 5A, voids PAG would be easily formed at the raw lateral surface PA123 interfacing directly the solder PAS and the lead PA12. In addition, since the lateral surface PA123 of the lead PA12 is not covered by the plating layer PA13, thus, after a long-time service or even storage in the atmosphere, oxidation would be a problem. Upon the oxidation of the lead PA12, difficulty in stabilizing the solder PAS and some other related problems might be encountered.

### SUMMARY OF THE INVENTION

In view that, since the lateral surface of the conventional lead is not coated by the plating layer, possible oxidation may ruin the welding and result in other problems, accordingly it is an object of the present invention to provide an electric device with terminal notches and a method for manufacturing the same electric device to resolve the aforesaid shortcomings in the prior art.

In the present invention, the electric device with terminal notches includes a main body, a plurality of SMT (Surface mount technology) leads and a plurality of plating layers. Each of the SMT leads is extended from the main body and ended up with a lead end surface furnished with a terminal notch, where the terminal notch has a notch peripheral surface. Each of the plating layers covers at least the notch peripheral surface of the corresponding SMT lead.

In one embodiment of the present invention, the plurality of SMT leads located at a same side of the main body is linearly arranged.

In one embodiment of the present invention, the terminal notches located at the same side of the main body are linearly arranged.

In one embodiment of the present invention, a cross section of the notch peripheral surface is an arc.

In one embodiment of the present invention, the cross section of the notch peripheral surface is a semicircular arc.

In one embodiment of the present invention, the plurality of plating layers is to cover individually a top surface and a bottom surface of the each of the plurality of SMT leads.

In another aspect of the present invention, a method for manufacturing the aforesaid electric device with terminal notches includes: a step (a) of preparing a plurality of main bodies interconnected by a plurality of connection leads; a step (b) constructing at least one through hole to each of the plurality of connection leads; a step (c) of performing a plating process upon the plurality of connection leads so as to coat a plating layer onto the each of the plurality of connection leads including the at least one through hole; and, a step (d) of, along at least one cutting line passing through the plurality of the through holes, cutting the plurality of connection leads so as to form the plurality of SMT leads and the terminal notches at the corresponding through holes, so that the notch peripheral surface of the terminal notch is covered by the corresponding plating layer.

In one embodiment of the present invention, the step (a) further includes: a step (a1) of cutting a lead frame into a plurality of unit lead frames, wherein each of the unit lead frames has a die attach region and the plurality of connection leads; a step (a2) of locating individually a plurality of discrete dies cut from a wafer onto the corresponding die attach regions of the respective unit lead frames; a step (a3) of, in each of the unit lead frames, a plurality of gold wires being introduced to connect the plurality of connection leads of the same unit lead frame and the die on the die attach region; and, a step (a4) of, in each of the unit lead frames, a package structure being formed to pack the die attach region, the die, the gold wires and part of each of the plurality of connection leads, so that the main bodies interconnected by the plurality of connection leads in the lead frame is thus prepared.

In one embodiment of the present invention, the step (b) further includes a step (b1) of constructing all the through holes along the plurality of connection leads arranged in parallel.

In one embodiment of the present invention, the step (d) further includes a step (d1) cutting the plurality of connection leads along at least one cutting line passing through center points of the corresponding through holes.

As stated, in the electric device with terminal notches and a method for manufacturing the same electric device provided by the present invention, the notch peripheral surface of the terminal notch increases the surface coverage of the plating layer over the SMT leads by providing the additional notch peripheral surface of the terminal notch to be plated. Thereupon, the contact area for soldering would be increased, the degree of oxidation would be reduced, and thus the weld strength can be increased.

All these objects are achieved by the electric device with terminal notches and the method for manufacturing the same electric device described below.

### BRIEF DESCRIPTION OF THE DRAWINGS

The present invention will now be specified with reference to its preferred embodiment illustrated in the drawings, in which:

FIG. 1 is a schematic view of an assembly of four conventional electric devices;

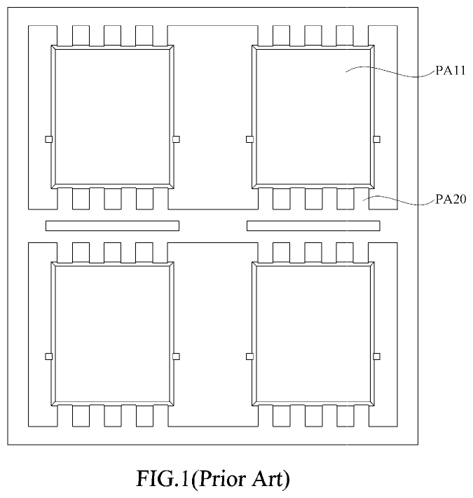

FIG. 2 is a schematic view of the four conventional electric devices of FIG. 1 after being separated;

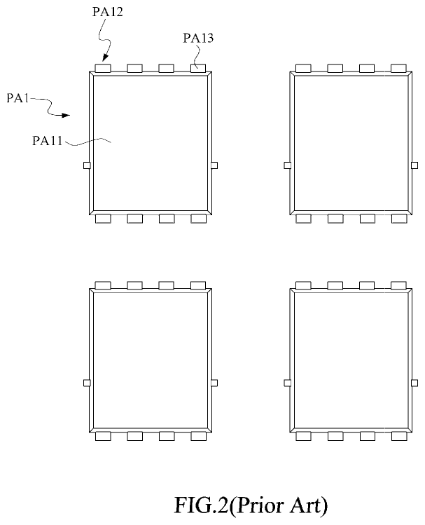

FIG. 3 is a schematic perspective view of the conventional electric device of FIG. 2;

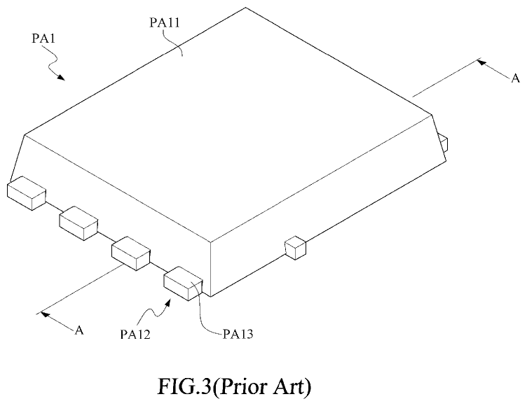

FIG. 4 is a schematic cross-sectional view of FIG. 3 along line A-A;

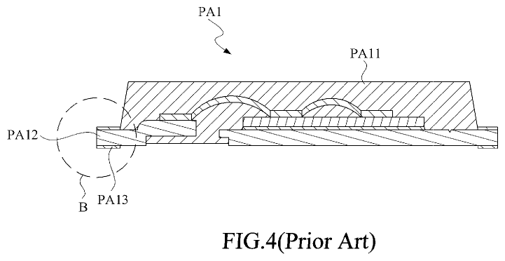

FIG. 4A is a schematic enlarged view of area B of FIG. 4;

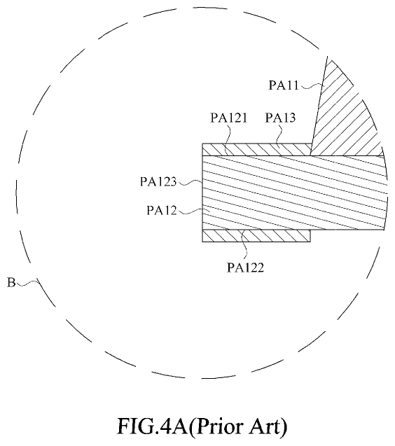

FIG. 5 is a schematic view of the conventional electric device of FIG. 4 on a circuit board;

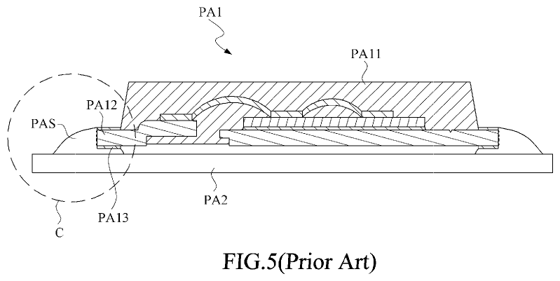

FIG. 5A is a schematic enlarged view of area C of FIG. 5;

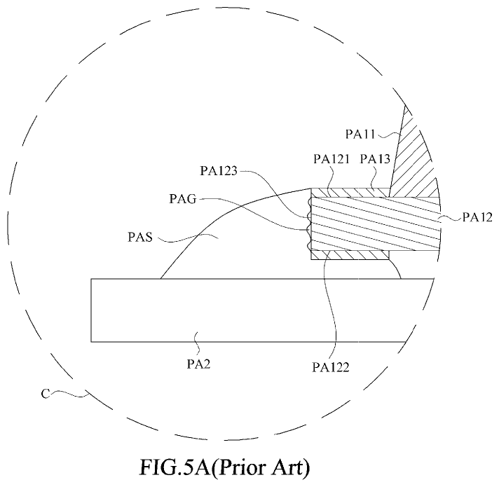

FIG. 6 is a schematic view of a preferred assembly of four electric devices in accordance with the present invention;

FIG. 7 is a schematic view of four preferred electric devices with terminal notches of FIG. 6 after being separated;

FIG. 8 is a schematic perspective view of the preferred electric device with terminal notches of FIG. 7;

FIG. 9 is a schematic cross-sectional view of FIG. 8 along line D-D;

FIG. 9A is a schematic enlarged view of area E of FIG. 9;

FIG. 10 is a schematic view of the preferred electric device with terminal notches of FIG. 9 on a circuit board;

FIG. 10A is a schematic enlarged view of area F of FIG. 10;

FIG. 11 is a flowchart of the preferred method for manufacturing the electric device in accordance with the present invention; and

FIG. 12 is a flowchart of Step S100 of FIG. 11.

### DESCRIPTION OF THE PREFERRED EMBODIMENT

The invention disclosed herein is directed to an electric device with terminal notches and a method for manufacturing the same electric device. In the following description, numerous details are set forth in order to provide a thorough understanding of the present invention. It will be appreciated by one skilled in the art that variations of these specific details are possible while still achieving the results of the present invention. In other instance, well-known components are not described in detail in order not to unnecessarily obscure the present invention.

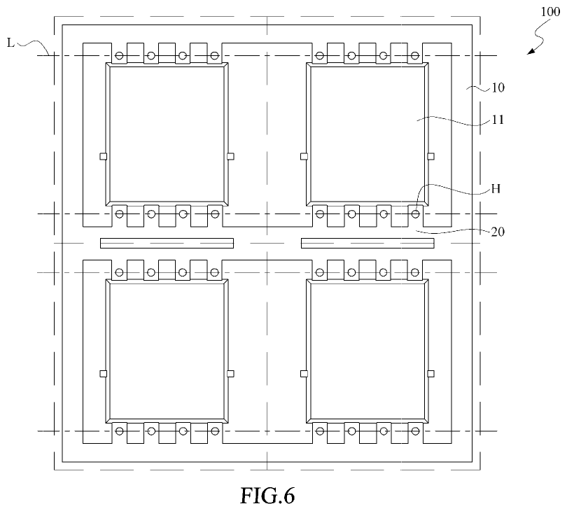

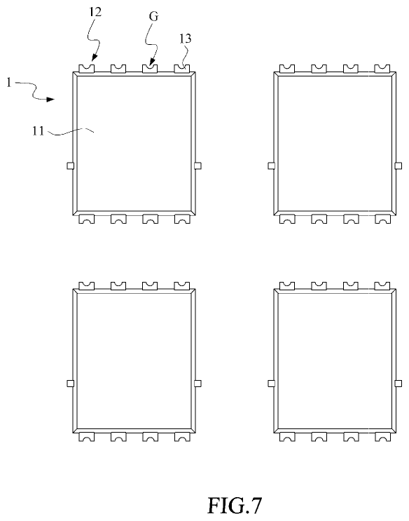

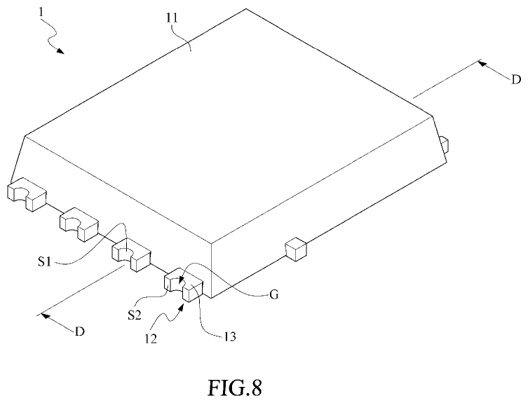

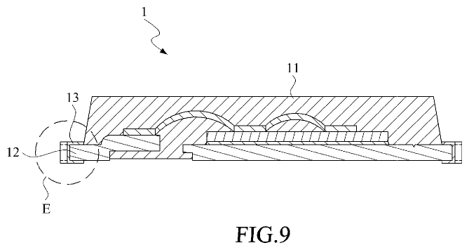

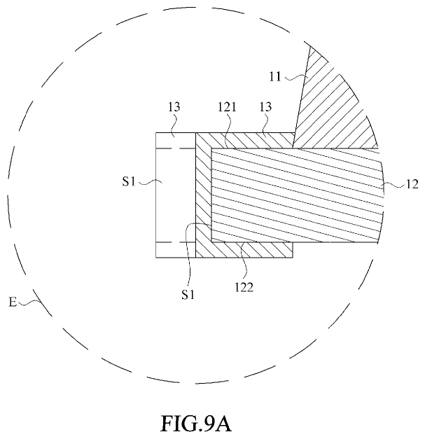

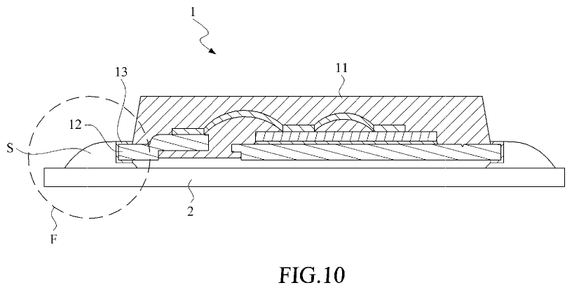

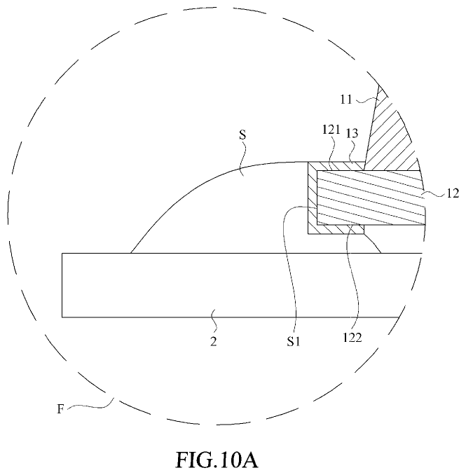

Refer now to FIG. 6 through FIG. 10A; where FIG. 6 is a schematic view of a preferred assembly of four electric devices in accordance with the present invention, FIG. 7 is a schematic view of four preferred electric devices with terminal notches of FIG. 6 after being separated, FIG. 8 is a schematic perspective view of the preferred electric device with terminal notches of FIG. 7, FIG. 9 is a schematic cross-sectional view of FIG. 8 along line D-D, FIG. 9A is a schematic enlarged view of area E of FIG. 9, FIG. 10 is a schematic view of the preferred electric device with terminal notches of FIG. 9 on a circuit board, and FIG. 10A is a schematic enlarged view of area F of FIG. 10.

In the present invention, a lead frame 100 includes a plurality of unit lead frames 10, and each of the unit lead frames 10 has a main body 11 and a plurality of connection leads 20. In particular, separate main bodies 11 of the lead frame 100 are also connected by the connection leads 20.

Each of the connection leads 20, in particular the connection lead 20 protruding from the corresponding main body 11, is furnished with at least one through hole H. In this embodiment shown in FIG. 6, each of the connection leads 20 located at the upper or lower portion of the figure is furnished with a through hole H, and each of the connection leads 20 in the middle portion of the figure is furnished with two through holes H. The connection leads 20 for the same electric device are distributed to two opposing sides of the main body 11, and the through holes H for the connection leads 20 at the same side of the main body 11 are linearly arranged. In addition, numbers of the connection leads 20 at individual sides of the main body 11 are the same.

Then, while in performing the plating, each of the connection leads 20 are coated with a plating layer 13. It shall be explained that the plating is performed only after the through hole H is provided to the corresponding connection lead 20. After the plating, the plating layer 13 would cover all the connection leads 20 and all the through holes H of the connection leads 20. Then, the connection leads 20 extending from the same side of the main body 11 are cut along a cutting line L connecting the respective linear-arranged through holes H, such that each connection lead 20 is thus transformed into an SMT lead 12, and the corresponding through hole H is cut to form a terminal notch G In particular, a notch peripheral surface S1 of the terminal notch G is covered by the plating layer 13. Finally, each of the unit lead frames 10 is thus formed as an electric device with terminal notches 1, as shown in FIG. 7. In FIG. 6, the cutting line L is drawn by a center line, and each of the unit lead frames 10 is enclosed by a dashed-line rectangle.

The electric device with terminal notches 1 includes a main body 11, a plurality of SMT leads 12 and a plurality of plating layers 13. Each of the SMT leads 12 extending from the main body 11 is ended up with a lead end surface S2, in which the SMT lead 12 is furnished with a terminal notches G on the lead end surface S2. As shown, the terminal notches G has a notch peripheral surface S1. In this embodiment, a cross section of the notch peripheral surface S1 is, but not limited to, a semicircular arc. In another embodiment not shown here, the cross section of the notch peripheral surface S1 can be an arc other than the aforesaid semicircular arc.

As described above, the plating layer 13 would cover both a top surface 121 and a bottom surface 122 of the SMT lead 12. In addition, according to this embodiment, since the through hole H is formed already before the connection lead 20 is plated, thus the plating layer 13 would also coat an interior wall of the through hole H. For the terminal notch G is formed from cutting the through hole H, so the notch peripheral surface S1 of the terminal notch G would be covered by the plating layer 13 as well, as shown in FIG. 9A. It shall be explained that, in FIG. 9A, the notch peripheral surface S1 completely coated by the plating layer 13 is denoted by dashed lines. In addition, a thickness of the plating layer 13 in the figure is only schematically demonstrated for a purpose of concise explanation, In practice, the thickness of the plating layer 13 is much thinner than that shown in the figure.

In comparison to the conventional lead PA12 whose lateral surface PA123 is entirely free from the plating layer PA13, the SMT lead 12 is furnished with the notch peripheral surface S1 to be covered by the plating layer 13, thus an accumulated area of the SMT lead 12 to be covered by the plating layer 13 is substantially increased. Also, due to the existence of the terminal notch G on the lead end surface S2, a portion of the lead end surface S2 of the SMT lead 12 that is not covered by the plating layer 13 would be comparatively smaller in area than the lateral surface PA123 of the conventional lead PA12. Thus, even after a long-time service or storage in the atmosphere, the degree of oxidation of the electric device with terminal notches 1, especially at the SMT leads 12, would be much smaller, in comparison with the prior art.

As shown in FIG. 10, the electric device with terminal notches 1 utilizes solders S to connect electrically and structurally with a circuit board 2. In practice, the solder S is usually a solder paste.

As shown, the solder S connects the plating layer 13, the SMT lead 12 and the circuit board 2. Since the plating layer 13 covers and so connects all the top surface 121, bottom surface 122 and notch peripheral surface S1 of the SMT lead 12 according to the present invention, thus the entire weld strength of the SMT lead 12 with the solder S can be substantially enhanced, and the existence of the voids at the interface of the solder S and the SMT lead 12 would be significantly reduced. In addition, the weld reliability can be increased as well. Thereupon, after being planted onto the circuit board 2 via the solders S, the electric device 1 of the present invention would be much more firmly adhered to the circuit board 2, in comparison with the prior art.

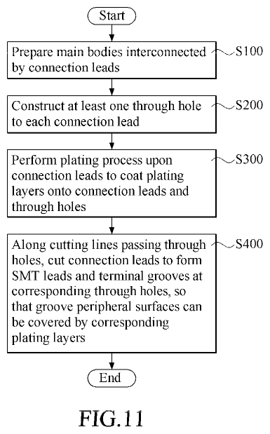

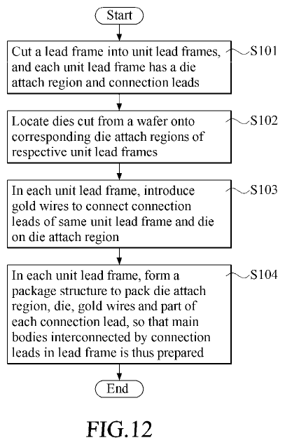

Then, refer to both FIG. 11 and FIG. 12; where FIG. 11 is a flowchart of the preferred method for manufacturing the electric device in accordance with the present invention, and FIG. 12 is a flowchart of Step S100 of FIG. 11.

As shown, the method for manufacturing the aforesaid electric device 1 with terminal notches of the present invention includes at least Step S100 through Step S400 as follows.

Step S100: Prepare a plurality of main bodies 11 interconnected by a plurality of connection leads 20.

Step S200: At each of the connection leads 20, at least one through hole H is constructed.

Preferably, the through holes H for the connection leads 20 located at the same lateral side of the main body 11 are linearly arranged, as shown in FIG. 6.

Step S300: A plating process is performed upon all the connection leads 20, so that all individual connection leads 20 including the through holes H are coated by corresponding plating layers 13.

Step S400: Along a cutting line L passing through the linear-arranged through holes, the corresponding connection leads 20 are cut so as to form the SMT leads 12 and thus the terminal notches G at the corresponding through holes H. In particular, the notch peripheral surface S1 of the terminal notch G is covered by the corresponding plating layer 13.

Preferably, the cross section of the notch peripheral surface S1 is formed as an arc or a semicircular arc. As shown in FIG. 6 to FIG. 8, the semicircular arc for the terminal notch G is formed to the exemplary example that the cutting line L passes through center points of the linear-arranged through holes H.

Referring Step S100 through Step S300 to FIG. 6, and Step S400 to FIG. 7 through FIG. 9A, related structural and formation details are already elucidated in the foregoing sections, and thus omitted herein. However, it shall be particularly explained that constructing of the through holes in Step S200 shall be performed prior to the plating process in Step S300, and thus the feature of the plating layer 13 covering the corresponding through hole H can be true to Step S400.

The Step S100 further includes the following Step S101 to S104.

S101: Cut a lead frame 100 into a plurality of unit lead frames 10, in which each of the unit lead frames 10 has a die attach region and a plurality of connection leads 20.

S102: Locate individually a plurality of discrete dies cut from a wafer onto corresponding die attach regions of the respective unit lead frames 10.

S103: In each of the unit lead frames 10, a plurality of gold wires are introduced to connect the connection leads 20 of the same unit lead frame 10 and the die on the die attach region.

S104: In each of the unit lead frames 10, a package structure is formed to pack the die attach region, the die, the gold wires and part of each of the individual connection leads 20. Thereupon, the main bodies 11 interconnected by the connection leads 20 in the lead frame 100 is now prepared.

In practice, Step S101 through Step S104 are common steps for manufacturing the main bodies. In the art, Step S101 and S102 stand for a die-saw process and a die-mount process, respectively, Step S103 stands for a wire-bond process, and Step S104 stands for a mold process.

In comparison with the prior art, the method for manufacturing the electric device provided by the present invention requires only an additional step to form the through holes to the corresponding connection leads. With modern technology, this additional step would not increase significant time and process difficulty, and thus the corresponding production yield would not be remarkably influenced. Nevertheless, with this additional step to supply the through holes, the electric device with terminal notches can be thus produced. In comparison to the conventional electric device, the electric device with terminal notches provided by the present invention can increase significantly the connection area between the solder and the corresponding SMT lead. Thereupon, the aforesaid conventional shortcomings at least in oxidation, weld strength and reliability can be substantially resolved.

In summary, in the electric device with terminal notches and a method for manufacturing the same electric device provided by the present invention, the notch peripheral surface of the terminal notch furnished to the lead end surface of the SMT lead is covered by the plating layer. In comparison with the prior art, the electric device with terminal notches of the present invention increases the surface coverage of the plating layer over the SMT leads by providing the notch peripheral surface of the terminal notch to be plated. Thereupon, the weld strength would be increased, and the degree of oxidation would be reduced. In addition, the formation of the through holes to the corresponding connection leads prior to the plating process in accordance with the method for manufacturing the electric device of the present invention does not increase significant time consumption and manufacturing difficulty, and thus mass production can be still carried out without substantially reducing the yield.

While the present invention has been particularly shown and described with reference to a preferred embodiment, it will be understood by those skilled in the art that various changes in form and detail may be without departing from the spirit and scope of the present invention.

What is claimed is:

1. An electric device with terminal notches, comprising:
a main body;
a plurality of SMT (Surface mount technology) leads, each of the plurality of SMT leads being extending from the main body and ended up with a lead end surface, the lead end surface being furnished with a terminal notch, the terminal notch having a notch peripheral surface; and
a plurality of plating layers, each of the plurality of plating layers covering at least the notch peripheral surface of the corresponding each of the plurality of SMT leads.

2. The electric device with terminal notches of claim 1, wherein the plurality of SMT leads located at a same side of the main body is linearly arranged.

3. The electric device with terminal notches of claim 2, wherein the terminal notches located at the same side of the main body are linearly arranged.

4. The electric device with terminal notches of claim 1, wherein a cross section of the notch peripheral surface is an arc.

5. The electric device with terminal notches of claim 4, wherein the cross section of the notch peripheral surface is a semicircular arc.

6. The electric device with terminal notches of claim 1, wherein the plurality of plating layers is to cover individually a top surface and a bottom surface of the each of the plurality of SMT leads.

7. A method for manufacturing an electric device, applied to the electric device with terminal notches of claim 1, comprising the steps of:
(a) preparing a plurality of main bodies interconnected by a plurality of connection leads;
(b) constructing at least one through hole to each of the plurality of connection leads;
(c) performing a plating process upon the plurality of connection leads so as to coat a plating layer onto the each of the plurality of connection leads including the at least one through hole; and
(d) along at least one cutting line passing through the plurality of the through holes, cutting the plurality of connection leads so as to form the plurality of SMT leads and the terminal notches at the corresponding through holes, so that the notch peripheral surface of the terminal notch is covered by the corresponding plating layer.

8. The method for manufacturing an electric device of claim 7, wherein the step (a) further includes the step of:
(a1) cutting a lead frame into a plurality of unit lead frames, wherein each of the unit lead frames has a die attach region and the plurality of connection leads;
(a2) locating individually a plurality of discrete dies cut from a wafer onto the corresponding die attach regions of the respective unit lead frames;
(a3) in each of the unit lead frames, a plurality of gold wires being introduced to connect the plurality of connection leads of the same unit lead frame and the die on the die attach region; and
(a4) in each of the unit lead frames, a package structure being formed to pack the die attach region, the die, the gold wires and part of each of the plurality of connection leads, so that the main bodies interconnected by the plurality of connection leads in the lead frame is thus prepared.

9. The method for manufacturing an electric device of claim 7, wherein the step (b) further includes a step (b1) of constructing all the through holes along the plurality of connection leads arranged in parallel.

10. The method for manufacturing an electric device of claim 7, wherein the step (d) further includes a step (d1) cutting the plurality of connection leads along at least one cutting line passing through center points of the corresponding through holes.
